(19) United States
(12) Patent Application Publication
(10) Pub. No.: US 2026/0164728 A1
(43) Pub. Date: Jun. 11, 2026

(54) GROUP III-V POWER SEMICONDUCTOR DEVICE AND METHOD OF MANUFACTURING SAME

(71) Applicant: DB HiTek Co., Ltd., Eumseong-gun (KR)

(72) Inventors: Jun Hyeok LEE, Eumseong-gun (KR); Woo Chul JEON, Eumseong-gun (KR); Ji Houn JUNG, Eumseong-gun (KR); Hee Sub LEE, Eumseong-gun (KR); Min Su CHO, Eumseong-gun (KR); Dong Hyeok SON, Eumseong-gun (KR); Ung Bi SON, Eumseong-gun (KR)

(21) Appl. No.: 19/074,582

(22) Filed: Mar. 10, 2025

(30) Foreign Application Priority Data
Dec. 6, 2024 (KR) 10-2024-0180269

(51) Int. Cl. H10D 62/10; H01L 21/324; H10D 30/01; H10D 30/47; H10D 62/60; H10D 62/824

(52) U.S. Cl. CPC H10D 62/102; H10D 30/015; H10D 30/474; H10D 30/4755; H10D 62/124; H10D 62/60; H10D 62/824; H10P 95/90

(57) ABSTRACT

Proposed are a group III-V power semiconductor device and a method of manufacturing the same. More particularly, proposed are a group III-V power semiconductor device in which one or more low-resistance regions are formed along a first direction substantially at the same height as a capping layer on a barrier layer, thereby relaxing the peak electric field between a gate electrode and a drain electrode so that the breakdown voltage characteristics of the device are improved, and a method of manufacturing the same.

### CROSS REFERENCE TO RELATED APPLICATION

The present application claims priority to Korean Patent Application No. 10-2024-0180269, filed Dec. 6, 2024, the entire contents of which is incorporated herein for all purposes by this reference.

### BACKGROUND

### Technical Field

The present disclosure relates to a group III-V power semiconductor device and a method of manufacturing the same. More particularly, the present disclosure relates to a group III-V power semiconductor device in which one or more low-resistance regions are formed along a first direction substantially at the same height as a capping layer on a barrier layer, thereby relaxing the peak electric field between a gate electrode and a drain electrode so that the breakdown voltage characteristics of the device are improved, and to a method of manufacturing the same.

### Description of the Related Art

Nitride-based semiconductors are being applied to high-withstand voltage and high-power semiconductor devices through high electron saturation velocity and wide band gap characteristics. In particular, gallium nitride (GaN) has high breakdown field characteristics and wide band gap characteristics compared to silicon and gallium arsenide (GaAs) and thus exhibits excellent breakdown voltage characteristics when applied to transistors.

In addition, GaN-based devices have high electron mobility and electron saturation velocity compared to silicon-based devices, which are currently commonly available, and therefore, can exhibit high frequency characteristics. In addition, the application of such high electron mobility to GaN-based devices allows for improved on-resistance characteristics, thereby enabling the implementation of low-loss switching devices.

As described above, GaN-based field effect transistors (FETs) are sufficiently advantageous as devices that require high-frequency and high-power characteristics, so ongoing research is in progress. While these GaN-based FETs have been widely studied and developed over the years, there are still several issues regarding device reliability that need to be addressed. Of all these, one important issue is the loss of a barrier layer.

FIG. 1 is a cross-sectional view illustrating an existing nitride-based power semiconductor device, and FIG. 2 is a reference view illustrating a process of forming an existing capping layer. Hereinafter, a structure of the existing semiconductor device and issues thereof will be described with reference to FIGS. 1 and 2.

Referring to FIG. 1, an existing nitride-based power semiconductor device 9 has a structure in which a buffer layer 910, a channel layer 920, and a barrier layer 930 are sequentially stacked on a substrate 901. In addition, a capping layer 940 of a p-GaN region is formed on the barrier layer 930, and a gate electrode 950 may be formed on the capping layer 940. A source electrode 971 and a drain electrode 973 may also be formed while being spaced from each other with the gate electrode 950 disposed therebetween. Furthermore, a two-dimensional electron gas (2 DEG) layer A may be formed in the channel layer 920 below the gate electrode 950. In this case, the 2 DEG layer A may be completely blocked below the gate electrode 950.

Such a structure enables the nitride-based power semiconductor device 9 to operate in an enhancement mode (E-mode), that is, normally-off operation. In other words, the 2 DEG layer A immediately below the capping layer 940 is deactivated, and when applying a positive voltage to the gate electrode 950, the device 9 may operate in a turn-on mode.

Referring to FIG. 2, the process of forming the above capping layer 940 is described as follows. First, a p-GaN layer 960 is formed on the barrier layer 930. The p-GaN layer 960 is then patterned utilizing a mask pattern M. The patterning of such a p-GaN layer 960 may be performed through a plasma etching process. When performing such a process, plasma damage may occur to the barrier layer 930 below the p-GaN layer 960. When the barrier layer 930 is unintentionally over-etched, this may result in issues with increased on-resistance of the device 9, leading to poor characteristics thereof.

To solve such a problem, the inventors of the present disclosure have proposed a novel group III-V power semiconductor device and a method of manufacturing the same, the contents of which will be described in detail later.

### DOCUMENTS OF RELATED ART

### Patent Document

Korean Patent Application Publication No. 10-2020-0068745 “High-Electron-Mobility Transistor”

### SUMMARY

The present disclosure, which has been devised to address the above-described issues in the related art, aims to provide a group III-V power semiconductor device in which one or more low-resistance regions are formed along a first direction substantially at the same height as a capping layer on a barrier layer, thereby controlling the resistance of a 2 DEG layer to be activated below the low-resistance region so that the on-resistance characteristics of the device are improved, and a method of manufacturing the same.

In addition, the present disclosure aims to provide a group III-V power semiconductor device in which one or more low-resistance regions are formed along a first direction substantially at the same height as a capping layer on a barrier layer, thereby relaxing the peak electric field between a gate electrode and a drain electrode so that the breakdown voltage characteristics of the device are improved, and a method of manufacturing the same.

In addition, the present disclosure aims to provide a group III-V power semiconductor device in which a low-resistance region is formed to be in contact with an edge side of a capping layer facing a drain electrode so that an electric field concentrated on an edge side of a gate electrode is easily relaxed, and a method of manufacturing the same.

In addition, the present disclosure aims to provide a group III-V power semiconductor device in which a low-resistance region is enabled to be formed in conjunction with a capping layer in a single layer so that an etching process is not performed when forming the capping layer and the low-resistance region, thus preventing possible damage to a barrier layer from occurring in advance to avoid degradation of the on-resistance characteristics of the device, and a method of manufacturing the same.

In addition, the present disclosure aims to provide a group III-V power semiconductor device in which a low-resistance region is enabled to be divided into a plurality of regions that differ from each other in resistance, thereby enabling flexible conformational changes depending on desired characteristics and the like, and a method of manufacturing the same.

In addition, the present disclosure aims to provide a group III-V power semiconductor device in which a hole injection region is formed to capture electrons trapped on one side adjacent to a barrier layer, thereby preventing current collapse from occurring and avoiding degradation of the on-resistance characteristics of the device, and a method of manufacturing the same.

The present disclosure may be implemented by embodiments having the following configurations to achieve the above-described objectives.

In one embodiment of the present disclosure, a group III-V power semiconductor device, according to the present disclosure, is characterized by including: a substrate; a channel layer on the substrate; a barrier layer on the channel layer; a capping layer on the barrier layer; a gate electrode on the capping layer; a source electrode and a drain electrode that are spaced from each other with the gate electrode disposed therebetween; and a low-resistance region between the capping layer and the drain electrode, the low-resistance region having a lower hole concentration than the capping layer.

In another embodiment of the present disclosure, the group III-V power semiconductor device, according to the present disclosure, is characterized in that the low-resistance region has a top surface that is substantially at the same height as a top surface of the capping layer.

In a further embodiment of the present disclosure, the group III-V power semiconductor device, according to the present disclosure, is characterized in that the low-resistance region is disposed even between the capping layer and the source electrode.

In a further embodiment of the present disclosure, the group III-V power semiconductor device, according to the present disclosure, is characterized in that the low-resistance region is in contact with a side wall of the gate electrode, the side wall being adjacent to the drain electrode.

In a further embodiment of the present disclosure, the group III-V power semiconductor device, according to the present disclosure, is characterized in that the low-resistance region includes: a first region between the capping layer and the drain electrode; and a second region between the first region and the drain electrode.

In a further embodiment of the present disclosure, the group III-V power semiconductor device, according to the present disclosure, is characterized in that the first region has a higher resistance than the second region.

In a further embodiment of the present disclosure, the group III-V power semiconductor device, according to the present disclosure, is characterized by further including: a first 2 DEG layer in the channel layer, immediately below the first region; and a second 2 DEG layer in the channel layer, immediately below the second region, wherein the first 2 DEG layer has a lower concentration than the second 2 DEG layer.

In a further embodiment of the present disclosure, a group III-V power semiconductor device, according to the present disclosure, is characterized by including: a substrate; a channel layer on the substrate; a barrier layer on the channel layer; a single layer including a capping layer and one or more low-resistance regions, along a first direction; a gate electrode on the capping layer; a source electrode and a drain electrode that are spaced from each other with the gate electrode disposed therebetween; and a hole injection region in the single layer, between the capping layer and the drain electrode, wherein the low-resistance region is disposed between the capping layer and the drain electrode.

In a further embodiment of the present disclosure, the group III-V power semiconductor device, according to the present disclosure, is characterized in that the hole injection region has a lower resistance than the capping layer.

In a further embodiment of the present disclosure, the group III-V power semiconductor device, according to the present disclosure, is characterized in that the hole injection region has a higher resistance than the low-resistance region.

In a further embodiment of the present disclosure, the group III-V power semiconductor device, according to the present disclosure, is characterized by further including a connection layer disposed on the hole injection region, the connection layer being electrically connected with the drain electrode.

In a further embodiment of the present disclosure, the group III-V power semiconductor device, according to the present disclosure, is characterized in that the connection layer is formed substantially in conjunction with the drain electrode in the same process.

In a further embodiment of the present disclosure, the group III-V power semiconductor device, according to the present disclosure, is characterized in that the low-resistance region includes: a first region between the capping layer and the drain electrode; and a second region between the first region and the drain electrode, and the first region is in contact with the second region.

In a further embodiment of the present disclosure, the group III-V power semiconductor device, according to the present disclosure, is characterized in that the low-resistance region is formed by an annealing process.

In one embodiment of the present disclosure, a method of manufacturing a group III-V power semiconductor device, according to the present disclosure, is characterized by including the following steps: sequentially forming a buffer layer, a channel layer, and a barrier layer on a substrate; forming a doped layer doped with a first conductivity type on the barrier layer; forming a capping layer and a low-resistance region in the doped layer; forming a source electrode and a drain electrode that are spaced from each other on the barrier layer, and forming a gate electrode on the capping layer, wherein the low-resistance region has a lower resistance value than the capping layer.

In another embodiment of the present disclosure, the method of manufacturing the group III-V power semiconductor device, according to the present disclosure, is characterized in that the step of forming the capping layer and the low-resistance region includes the following steps: forming a first mask pattern on the doped layer so that a side where the capping layer is to be formed is open; forming a pre-capping layer by performing a first annealing process along the open side of the first mask pattern; forming a second mask pattern on the pre-capping layer and the doped layer so that sides where the capping layer is to be formed and where the low-resistance region is to be formed are open; and forming the capping layer and the low-resistance region by performing a second annealing process along the open sides of the second mask pattern.

In a further embodiment of the present disclosure, the method of manufacturing the group III-V power semiconductor device, according to the present disclosure, is characterized in that the first and second annealing processes are performed at an annealing temperature in the range of about 300° C. to 1000° C. in a vacuum atmosphere.

In a further embodiment of the present disclosure, the method of manufacturing the group III-V power semiconductor device, according to the present disclosure, is characterized in that the step of forming the capping layer and the low-resistance region includes the following steps: forming a third mask pattern on the doped layer so that a side where the low-resistance region is to be formed is open; and forming the low-resistance region by performing an ion implantation process along the open side of the third mask pattern.

In a further embodiment of the present disclosure, the method of manufacturing the group III-V power semiconductor device, according to the present disclosure, is characterized by further including a step of dividing the low-resistance region into a first region and a second region that has a lower resistance than the first region, wherein the step of dividing the low-resistance region into the first and second regions includes the following steps: forming a fourth mask pattern on the doped layer so that a side where the second region is to be formed is open; and forming the second region by performing an ion implantation process along the open side of the third mask pattern.

In a further embodiment of the present disclosure, the method of manufacturing the group III-V power semiconductor device, according to the present disclosure, is characterized in that the ion implantation process is performed through ion implantation of one or more elements of Ar, N, O, Si, and H.

The present disclosure has the following effects based on the above-described configurations.

The present disclosure has an effect of forming one or more low-resistance regions along a first direction substantially at the same height as a capping layer on a barrier layer, thereby controlling the resistance of a 2 DEG layer to be activated below the low-resistance region so that the on-resistance characteristics of the device are improved.

In addition, the present disclosure has an effect of forming one or more low-resistance regions along a first direction substantially at the same height as a capping layer on a barrier layer, thereby relaxing the peak electric field between a gate electrode and a drain electrode so that the breakdown voltage characteristics of the device are improved.

In addition, the present disclosure derives an effect of forming a low-resistance region to be in contact with an edge side of a capping layer facing a drain electrode so that an electric field concentrated on an edge side of a gate electrode is easily relaxed.

In addition, the present disclosure shows an effect of enabling a low-resistance region to be formed in conjunction with a capping layer in a single layer so that an etching process is not performed when forming the capping layer and the low-resistance region, thus preventing possible damage to a barrier layer from occurring in advance to avoid degradation of the on-resistance characteristics of the device.

In addition, the present disclosure shows an effect of enabling a low-resistance region to be divided into a plurality of regions that differ from each other in resistance, thereby enabling flexible conformational changes depending on desired characteristics and the like.

In addition, the present disclosure has an effect of forming a hole injection region to capture electrons trapped on one side adjacent to a barrier layer, thereby preventing current collapse from occurring and avoiding degradation of the on-resistance characteristics of the device.

In the meantime, it is further stated that even when not explicitly mentioned herein, the effects hereinafter expected by the technical features of the present disclosure and potential effects thereof are treated as those described herein of the present disclosure.

### BRIEF DESCRIPTION OF THE DRAWINGS

FIG. 1 is a cross-sectional view illustrating an existing nitride-based power semiconductor device;

FIG. 2 is a reference view illustrating a process of forming an existing capping layer;

FIG. 3 is a plan view illustrating a group III-V power semiconductor device according to one embodiment of the present disclosure;

FIG. 4 is a cross-sectional view along the line AA′ illustrating the group III-V power semiconductor device based on FIG. 3; and

FIGS. 5 to 15 are cross-sectional views illustrating a method of manufacturing a group III-V power semiconductor device according to one embodiment of the present disclosure.

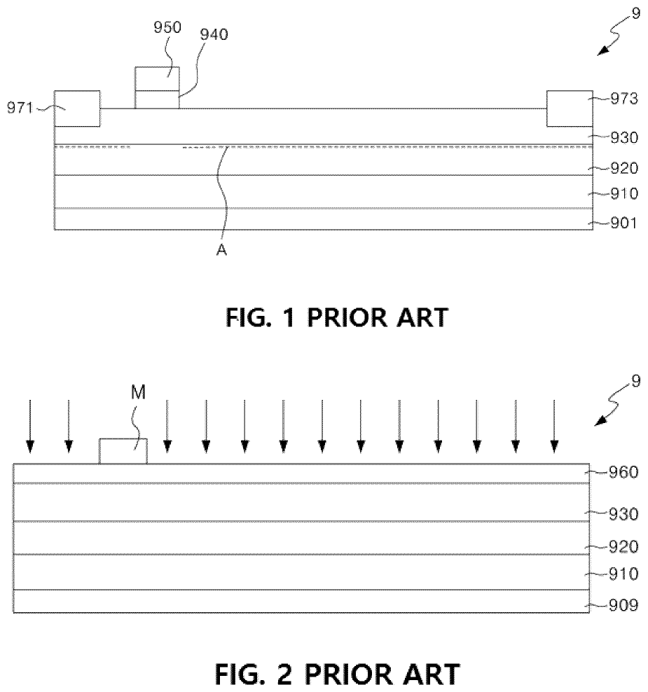

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the following embodiments but should be construed on the basis of the appended claims. In addition, these embodiments are only provided for reference to more completely describe the present disclosure to those of ordinary skill in the art to which the present disclosure pertains.

Hereinafter, it should be noted that when one component (or layer) is described as being disposed on another component (or layer), one component may be disposed directly on another component, or another component(s) or layer(s) may be disposed between the components. In addition, when one component is expressed as being directly disposed on or above another component, no other component(s) are disposed between the components. Furthermore, being disposed “on”, “on an upper portion of”, “on a lower portion of”, “above”, “below”, “on one (first) side of”, or “on one side surface of” a component implies a relative positional relationship.

In addition, terms such as first, second, and the like may be used to describe various items, such as various elements, regions, and/or portions, but these items are not limited by such terms.

It should also be noted that when certain embodiments are implementable otherwise, certain processes may be performed in an order that differs from that described below. For example, two processes described sequentially may be substantially performed simultaneously or inversely.

Furthermore, a conductivity type or a doped region of components may be defined as “p-type” or “n-type” depending on the characteristics of main carriers, but this is only for the benefit of description, and the technical idea of the present disclosure is not limited as exemplified. For example, the more general term “first conductivity type” or “second conductivity type” will be used hereinafter for the “p-type” or “n-type”. In this case, the first conductivity type refers to the p-type, and the second conductivity type refers to the n-type.

It should also be understood that the terms “high concentration” and “low concentration” that express doping concentrations of impurity regions may refer to relative doping concentrations of one component and other components.

In a plan view illustrated, an x-axis direction is set as a “first direction”, while a y-axis direction is set as a “second direction”.

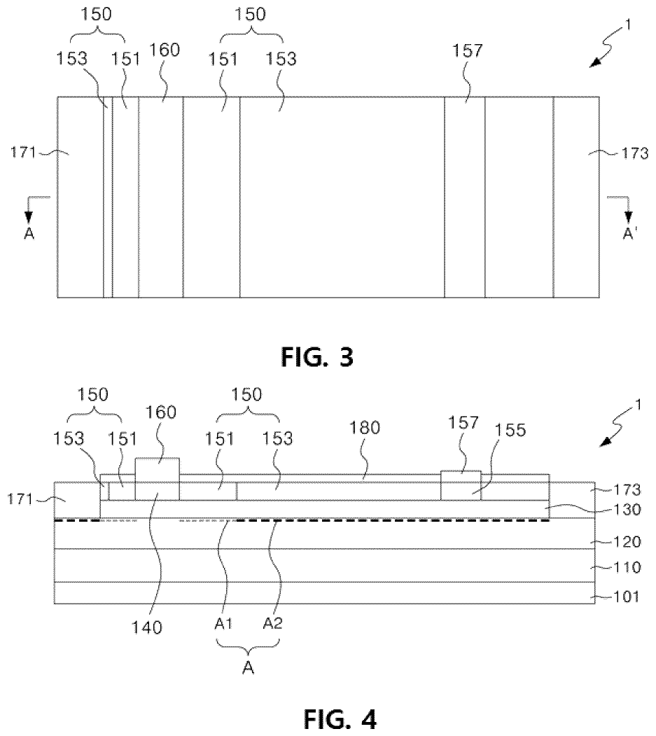

FIG. 3 is a plan view illustrating a group III-V power semiconductor device according to one embodiment of the present disclosure, and FIG. 4 is a cross-sectional view along the line AA′ illustrating the group III-V power semiconductor device based on FIG. 3. It should be noted that in the plan view illustrated in FIG. 3, an insulation film is omitted.

Hereinafter, a power semiconductor device 1, according to the one embodiment of the present disclosure, will be described in detail with reference to the attached drawings.

Referring to FIGS. 3 and 4, the present disclosure relates to the group III-V power semiconductor device 1. More particularly, the present disclosure relates to the group III-V power semiconductor device 1 in which one or more low-resistance regions 150 are formed along the first direction substantially at the same height as a capping layer 140 on a barrier layer 130, thereby relaxing the peak electric field between a gate electrode 160 and a drain electrode 173 so that the breakdown voltage characteristics of the device 1 are improved. The expression “substantially at the same height as” is understood to mean that the low-resistance region 150 and the capping layer 140 are formed in a single layer because separate etching processes are not performed when forming the low-resistance region 150 and the capping layer 140.

First, the group III-V power semiconductor device 1, according to one embodiment of the present disclosure, may include a substrate 101. The substrate 101, which is a substrate for growth, may, for example, be a silicon substrate, but there are no limitations. Other examples thereof may include a sapphire substrate, a GaN substrate, or a SiC substrate. In the present disclosure, an example where the substrate 101 is a silicon substrate is to be described.

In addition, a buffer layer 110 may be formed on the substrate 101. The buffer layer 110 may be formed, for example, by growing AlN on the substrate 101 to a predetermined thickness. Alternatively, the buffer layer 110 may have a form in which a single layer of GaN or AlGaN or a composite layer of one or more of the foregoing GaN and AlGaN is grown, but there are no limitations. Such a buffer layer 110 may be a structure configured to prevent stress caused by differences in lattice constants and thermal expansion coefficients of the substrate 101 and a channel layer 120 to be described later. The buffer layer 110 may also be doped with impurities such as C and/or Fc.

The channel layer 120 is formed to have a predetermined thickness on the substrate 101, more preferably on the buffer layer 110, and may, for example, be made of a semiconductor layer based on a nitride such as GaN. In addition, the barrier layer 130 is formed to have a predetermined thickness on the channel layer 120 and may, for example, be a semiconductor layer based on a nitride such as AlGaN. Such channel layer 120 and barrier layer 130 are preferably formed of nitride-based semiconductor layers that differ from each other. In one example, the channel layer 120 and the barrier layer 130 may also include a material formed by a difference in composition ratio based on a combination of x and y in an AlxInyGa1-x-y material (x+y<1). In addition, the barrier layer 130 may include a material that has a wider band gap than that of the channel layer 120.

On the basis of such a structure, a 2 DEG layer A may be formed near the interface between the channel layer 120 and the barrier layer 130. In this case, the density and mobility of the 2 DEG layer A may be controlled by adjusting the Al and Ga contents in the barrier layer 130. The 2 DEG layer A may be formed in the channel layer 120. In addition, to increase the concentration of the 2 DEG layer A (or to reduce the resistance), a method of increasing the Al composition in the barrier layer 130, which is an AlGaN layer, or increasing the vertical thicknesses of the barrier layer 130 may, for example, be adopted.

In addition, the capping layer 140 may be formed on the barrier layer 130. The capping layer 140, which is configured to be formed between the barrier layer 130 and the gate electrode 160, preferably has a positive polarity, for example, of the first conductive type. When such a capping layer 140 is formed to a predetermined or larger thickness, the gate electrode 160 and the 2 DEG layer A become more distant, resulting in a longer response time. In contrast, when formed to a predetermined or smaller thickness, it is difficult to achieve the normally-off operation. Therefore, the thickness thereof is preferably formed at a suitable level, which is, for example, in the range of 10 nm to 1000 nm, but there are no limitations. In addition, the capping layer 140 may be formed by growing p-GaN and may, for example, be formed by doping GaN with Mg.

In addition, one or more low-resistance regions 150 may be formed along the first direction between the capping layer 140 and the drain electrode 173. In some cases, the low-resistance region 150 may also be formed along the first direction between the capping layer 140 and a source electrode 171. The low-resistance region 150 is formed on the barrier layer 130, such that the top surface thereof may be formed planarly at substantially the same height as the top surface of the capping layer 140.

In general, when forming the capping layer 140 on the barrier layer 130, a doped layer, such as a p-GaN layer, may, for example, be formed on the barrier layer 130, followed by etching the remaining doped layer except for the region immediately below where the gate electrode 160 is to be formed. In this case, the etching process is dry etching, which may, for example, be a plasma etching process. In the plasma etching process, unintentional plasma damage may occur to the barrier layer 130 below the etched side of the doped layer. This plasma damage results in increased resistance of the 2 DEG layer A in the channel layer 120, which may cause the issue where the reliability of the device 1 is undermined.

To address such an issue, the group III-V power semiconductor device 1, according to one embodiment of the present disclosure, is characterized in that the 2 DEG layer A is enabled to be formed even without etching the doped layer when forming the capping layer 140. In this case, the doped layer in the region immediately below the gate electrode 160 functions as the capping layer 140, and the doped layer between the gate electrode 160 and the drain electrode 173 may function as the low-resistance region 150. Thus, the low-resistance region 150 is formed on the barrier layer 130, as described above, such that the top surface thereof is enabled to be formed planarly at substantially the same height as the top surface of the capping layer 140. The low-resistance region 150 may be formed by performing an annealing process or an ion implantation process on the doped layer, which will be described in more detail later.

In addition, the low-resistance region 150 may include a plurality of regions that differ from each other in resistance value between the capping layer 140 and the drain electrode 173, along the first direction. For example, a first region 151 may be formed on one side relatively adjacent to the capping layer 140, while a second region 153 may be formed on one side relatively distant from the capping layer 140. In this case, the first region 151 and the second region 153 may be in contact with or spaced apart from each other along the first direction. Furthermore, the first region 151 preferably has a higher resistance than the second region. In one example, the first region 151 may have a higher hole concentration than the second region 153. Thus, a first 2 DEG layer A1 immediately below the first region 151 may have a lower concentration than a second 2 DEG layer A2 immediately below the second region 153.

In general, between the gate electrode 160 and the drain electrode 173, the electric field is concentrated at the edge of the gate electrode 160. Thus, to relax the concentrated electric field, the first region 151 is preferably formed to be in contact with the side wall of the capping layer 140 adjacent thereto. It should also be noted that, unlike the foregoing description, the low-resistance region 150 may be formed of a single region or three or more regions.

In addition, in some cases, a hole injection region 155 may be further formed on the side adjacent to the drain electrode 173, between the gate electrode 160 and the drain electrode 173. Such a hole injection region 155 is where holes are injected to capture electrons trapped on the side adjacent to the barrier layer 130. In other words, holes are injected into the 2 DEG layer A via the hole injection region 155, thereby allowing such holes to bind to trapped electrons so that the electrical resistance of the device 1 is reduced, and the memory effect is thus minimized. Furthermore, the hole injection region 155 may be formed substantially in the same manner as the low-resistance region 150. The hole injection region 155 may also have a higher resistance than the low-resistance region 150. In one example, the hole injection region 155 may have a lower resistance than the capping layer 140 and a higher resistance than the low-resistance region 150, but the scope of the present disclosure is not limited thereto. Thus, holes may be injected via the hole injection region 155.

In addition, a connection layer 157 may be further formed on the hole injection region 155. The connection layer 157, a region in contact with the hole injection region 155, may be electrically connected with the drain electrode 173. Preferably, such a connection layer 157 is formed in conjunction substantially during the processes of forming the source electrode 171 and/or the drain electrode 173 to prevent the overall process efficiency from being reduced. Thus, the connection layer 157 preferably includes the same material as the drain electrode 173 and is more preferably made of the same material.

For the following description, the gate electrode 160 may be formed on the capping layer 140. The gate electrode 160 may, for example, be formed of a single layer or composite layer made of various metals, such as Ti and Pd. The depletion layer of such a gate electrode 160 may penetrate the barrier layer 130, reaching the channel layer 120 and thus blocking the 2 DEG layer A to enable the normally-off operation of the device 1.

In addition, the source electrode 171 and the drain electrode 173 may be formed on the barrier layer 130 while being spaced from each other. In some cases, the source electrode 171 and the drain electrode 173 may be formed such that the lower portions thereof are disposed in the barrier layer 130, on the interface between the barrier layer 130 and the channel layer 120, in the channel layer 120, or on the barrier layer 130. However, there are no particular limitations.

The source electrode 171 and the drain electrode 173 may be disposed in an active region while being spaced from each other with the gate electrode 160 disposed therebetween. Such source electrode 171 and drain electrode 173, which are ohmic contact regions, may, for example, have a square cross-sectional shape or a stepped cross-sectional shape. However, the scope of the present disclosure is not limited by any particular examples. In addition, the source electrode 171 and the drain electrode 173 may, for example, include a single layer or composite layer made of various metals capable of ohmic contact, such as Ti, Au, and Al. However, there are no particular limitations.

In addition, an insulation film 180 may be formed on the barrier layer 130 and the low-resistance region 150. The insulation film 180 may be made of an electrically insulating material, for example, Al₂O₃, but there are no particular limitations, and may also include any oxide film, nitride film, or the like.

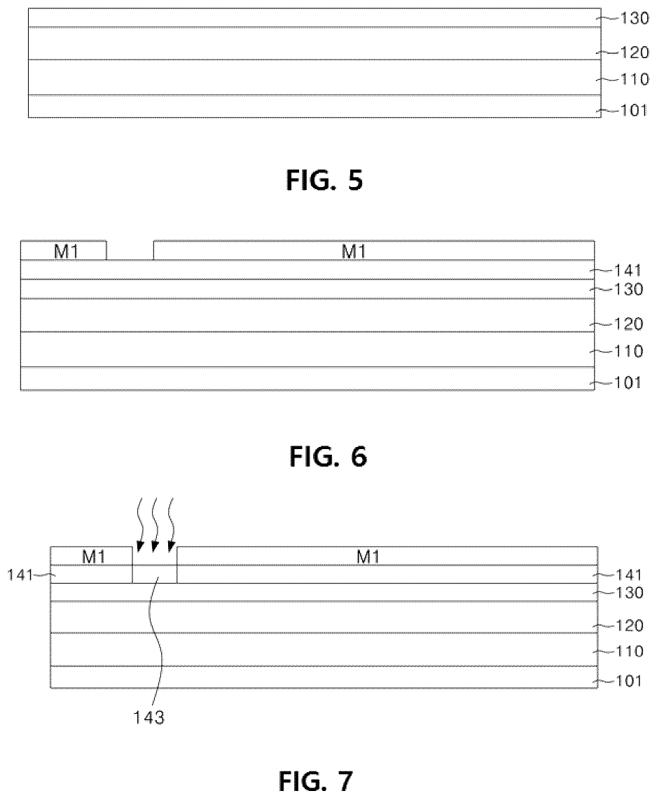

FIGS. 5 to 15 are cross-sectional views illustrating a method of manufacturing a group III-V power semiconductor device according to one embodiment of the present disclosure.

Hereinafter, a method of manufacturing a group III-V power semiconductor device 1, according to one embodiment of the present disclosure, will be described in detail with reference to the attached drawings.

Referring to FIG. 5, a buffer layer 110, a channel layer 120, and a barrier layer 130 may first be formed sequentially on a substrate 101. The substrate 101, which is a substrate for growth as described above, may be any one of a silicon substrate, a sapphire substrate, a GaN substrate, and a SiC substrate, but the description in the present disclosure is based on the case being a silicon substrate as one example. The buffer layer 110 may be formed on the substrate 101 and under the channel layer 120, for example, by growing an AlN layer to a predetermined thickness. In addition, the channel layer 120 to be formed on the buffer layer 110 is a semiconductor layer based on a nitride such as GaN, and the barrier layer 130 is a semiconductor layer based on a nitride such as AlGaN. By electrons accumulated at the interface between the channel layer 120 and the barrier layer 130, a 2 DEG layer A may be formed.

For a detailed description, piezoelectric polarization may occur at the interface between the channel layer 120 and the barrier layer 130, for example, due to differences in lattice constants of GaN and AlGaN. In this case, the piezoelectric polarization effect and the spontaneous polarization effect of the channel layer 120 and the barrier layer 130 may function, thereby generating two-dimensional electron gas with a high electron concentration at the interface between the two configurations.

Then, a capping layer 140 and a low-resistance region 150 may be formed on the barrier layer 130. Next, a hole injection region 155 may be additionally formed as needed. The capping layer 140, the low-resistance region 150, and the hole injection region 155 may be formed sequentially along the first direction. Hereinafter, the processes of forming the capping layer 140, the low-resistance region 150, and the hole injection region 155 will be described in detail.

Referring to FIG. 6, a doped layer 141 grown with the first conductivity type may, for example, be formed first on the barrier layer 130. Thereafter, a first mask pattern M1 may be formed on the doped layer 141. The first mask pattern M1 may be formed such that the top surface of the doped layer 141 on the side where the capping layer 140 is to be formed is open. The first mask pattern M1 may include an oxide film, a nitride film, an oxynitride film, or the like.

Referring to FIG. 7, an annealing process may then be performed along the open side of the first mask pattern M1. In this case, the annealing may be performed for about 3 to 10 minutes, and the annealing may be performed at a temperature in the range of about 300° C. to 1000° C.

In one example, the doped layer 141 has high resistance and low electrical conductivity. This is because an Mg—H bond, which is electrically deactivated, is formed by H. Therefore, performing the annealing process, for example, in an inert atmosphere may break the Mg—H bond and activate Mg, thus transforming the doped layer 141, which is a Mg-doped GaN thin film, into the first conductivity type. Accordingly, a pre-capping layer 143 may be formed on one side of the doped layer 141. Subsequently, the first mask pattern M1 is removed.

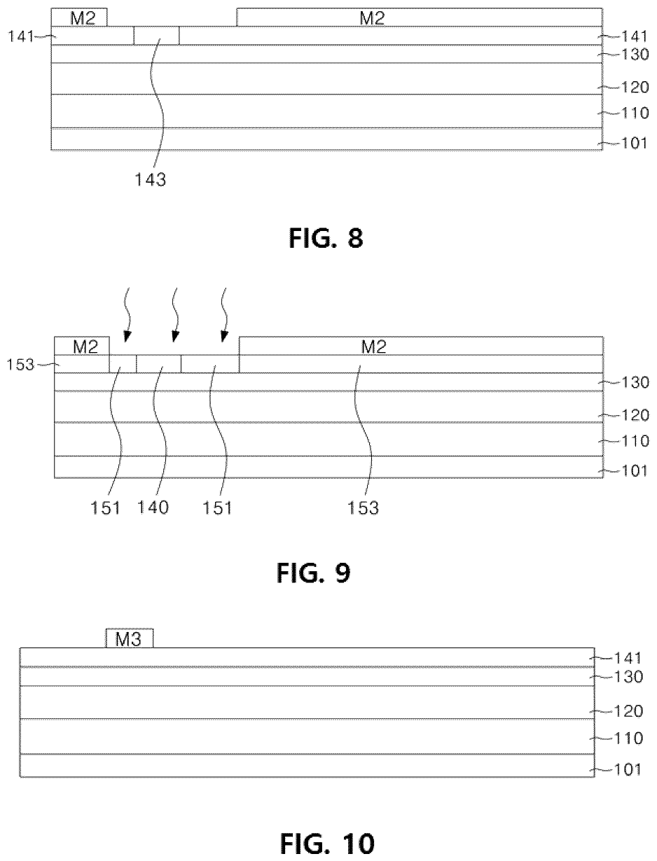

Referring to FIG. 8, a second mask pattern M2 may then be formed on the doped layer 141. The second mask pattern M2 may be formed such that the top surface of the doped layer 141 on the side where the pre-capping layer 143 and the low-resistance region 150 are to be formed is open. The second mask pattern M2 may also include an oxide film, a nitride film, an oxynitride film, or the like.

Referring to FIG. 9, an annealing process may then be performed again along the open side of the second mask pattern M2. In this case, the annealing may be performed for about 3 to 10 minutes, and the annealing may be performed at a temperature in the range of about 300° C. to 1000° C. When performing the annealing process, the pre-capping layer 143 becomes the capping layer 140, and the low-resistance region 150 may be formed in the remaining region of the doped layer 141. In this case, conforming to the shape of the second mask pattern M2, a first region 151 and a second region 153 may be formed in the low-resistance region 150. Subsequently, the second mask pattern M2 is removed. Then, a mask pattern may be formed again on the doped layer 141, and an annealing process may be performed, thereby forming the hole injection region 155. In addition, in the above example, the number of annealing processes is not limited.

Alternatively, the low-resistance region 150 may be formed in a manner that differs from what is described above. This will be described in detail. Referring to FIG. 10, a third mask pattern M3 may first be formed on the doped layer 141. The third mask pattern M3 may be configured substantially in the same manner as the first mask pattern M1. The third mask pattern M3 may also be formed on the top surface of the doped layer 141 on the side where the capping layer 140 is to be formed, such that the top surface of the doped layer 141 on the side where the low-resistance region 150 is to be formed is open.

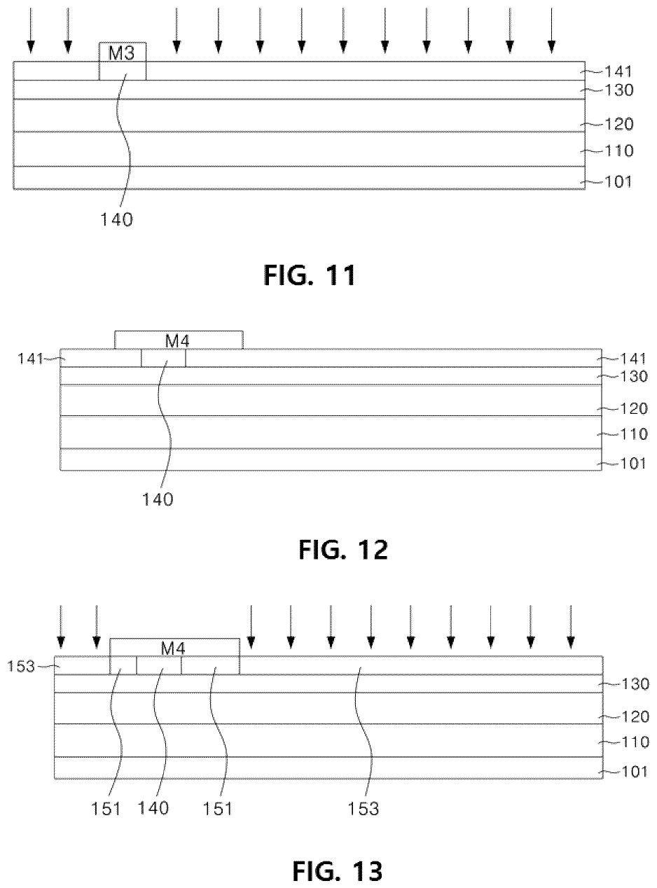

Referring to FIG. 11, ion implantation of one or more elements of Ar, N, O, Si, and H may then be performed on the open side of the doped layer 141, thereby forming the low-resistance region 150. In one example, the ion implantation of H element into the doped layer 141 may passivate the doped layer 141 made of Mg-doped GaN. Therefore, the hole concentration in the doped layer 141 may be reduced, and the 2 DEG layer A having a relatively high concentration may be formed below the low-resistance region 150. In another example, the ion implantation of elements such as Ar and/or N into the doped layer 141 may cause lattice damage in the doped layer 141 based on p-GaN, thereby reducing the polarization charge of the doped layer 141. On this basis, the 2 DEG layer A having a relatively high concentration may be formed below the low-resistance region 150. In addition, the ion implantation of H element into the doped layer 141 at high energy and/or high concentration may cause lattice damage in the capping layer 140. By this process, the capping layer 140 may be separated from the low-resistance region 150. Subsequently, the third mask pattern M3 is removed.

Referring to FIG. 12, a fourth mask pattern M4 may be formed on the top surface of the capping layer 140 and the low-resistance region 150. The fourth mask pattern M4 may be configured substantially in the same manner as the third mask pattern M3. The fourth mask pattern M4 may also be formed on the top surface on the side where the capping layer 140 and the first region 151 are to be formed, such that the top surface on the side where the second region 153 is to be formed is open.

Referring to FIG. 13, an ion implantation process may then be performed, thereby forming the second region 153. In the ion implantation process, one or more elements of Ar, N, O, Si, and H may be implanted into the low-resistance region 150, thereby forming the second region 153. Subsequently, the fourth mask pattern M4 is removed.

Then, a mask pattern may be formed again on the doped layer 141, and an ion implantation process may be performed, thereby forming the hole injection region 155. In addition, in the above example, the number of ion implantation processes is not limited.

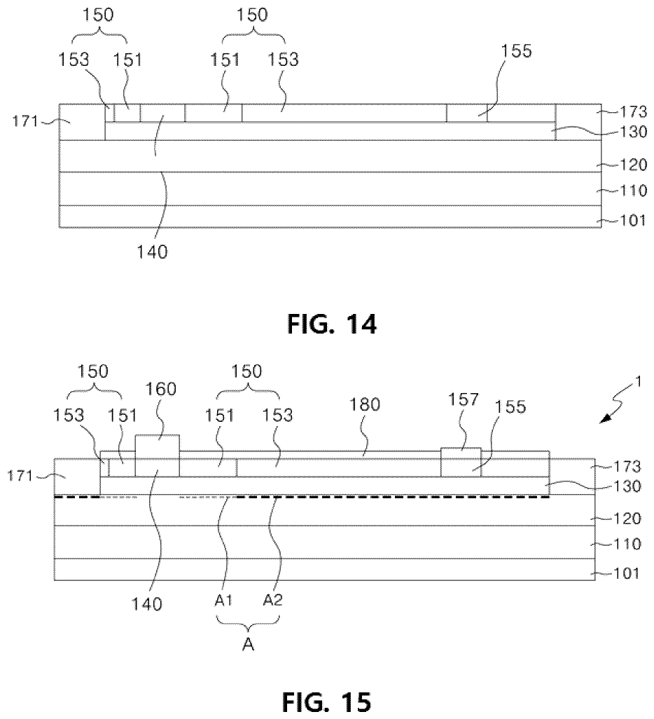

Referring to FIG. 14, a source electrode 171 and a drain electrode 173 may then be formed at given locations. The source electrode 171 and the drain electrode 173 may be formed by depositing a metal layer (not shown) and performing an etching process. In this process, a connection layer 157 is preferably formed in conjunction.

Referring to FIG. 15, an insulation film 180 may then be formed on the capping layer 140 and the low-resistance region 150. Then, a gate electrode 160 may be formed by etching the insulation film 180, depositing a gate film (not shown), and performing an etching process.

The detailed description above is illustrative of the present disclosure. In addition, the description above shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art to which the present disclosure pertains. The above-described embodiments describe the best state for implementing the technical idea of the present disclosure, and various changes required in the specific application field and use of the present disclosure are possible. Therefore, the detailed description of the present disclosure above is not intended to limit the present disclosure to the embodiments disclosed herein.

What is claimed is:

1. A group III-V power semiconductor device comprising:
a substrate;
a channel layer on the substrate;
a barrier layer on the channel layer,
a capping layer on the barrier layer;
a gate electrode on the capping layer,
a source electrode and a drain electrode that are spaced from each other with the gate electrode therebetween; and
a low-resistance region between the capping layer and the drain electrode, the low-resistance region having a lower hole concentration than the capping layer.

2. The power semiconductor device of claim 1, wherein the low-resistance region has a top surface that is substantially coplanar with a top surface of the capping layer.

3. The power semiconductor device of claim 1, wherein the low-resistance region is between the capping layer and the source electrode in a horizontal plane parallel with an uppermost surface of the substrate.

4. The power semiconductor device of claim 1, wherein the low-resistance region is in contact with one or more side walls of the capping layer and one or more side walls of the source electrode and/or the drain electrode.

5. The power semiconductor device of claim 1, wherein the low-resistance region comprises:
a first region between the capping layer and the drain electrode; and
a second region between the first region and the drain electrode.

6. The power semiconductor device of claim 5, wherein the first region has a higher resistance than the second region.

7. The power semiconductor device of claim 5, further comprising:
a first two-dimensional electron gas (2 DEG) layer in the channel layer, immediately below the first region; and
a second 2 DEG layer in the channel layer, immediately below the second region,
wherein the first 2 DEG layer has a lower concentration than the second 2 DEG layer.

8. A group III-V power semiconductor device comprising:
a substrate;
a channel layer on the substrate;
a barrier layer on the channel layer;
a single layer comprising a capping layer and one or more low-resistance regions, along a first direction;
a gate electrode on the capping layer,
a source electrode and a drain electrode that are spaced from each other with the gate electrode therebetween; and
a hole injection region in the single layer, between the capping layer and the drain electrode,
wherein the low-resistance region is between the capping layer and the drain electrode.

9. The power semiconductor device of claim 8, wherein the hole injection region has a lower resistance than the capping layer.

10. The power semiconductor device of claim 8, wherein the hole injection region has a higher resistance than the low-resistance region.

11. The power semiconductor device of claim 8, further comprising:
a connection layer on the hole injection region, the connection layer being electrically connected with the drain electrode.

12. The power semiconductor device of claim 11, wherein the connection layer is formed substantially in conjunction with the drain electrode in a same process.

13. The power semiconductor device of claim 8, wherein the low-resistance region comprises:
a first region between the capping layer and the drain electrode; and
a second region between the first region and the drain electrode, wherein
the first region is in contact with the second region.

14. The power semiconductor device of claim 8, wherein the low-resistance region is formed by an annealing process.

15. A method of manufacturing a group III-V power semiconductor device, the method comprising:
sequentially forming a buffer layer, a channel layer, and a barrier layer on a substrate;
forming a doped layer doped with a first conductivity type on the barrier layer;
forming a capping layer and a low-resistance region in the doped layer;
forming a source electrode and a drain electrode that are spaced from each other on the barrier layer, and
forming a gate electrode on the capping layer, wherein the low-resistance region has a lower resistance than the capping layer.

16. The method of claim 15, wherein forming the capping layer and the low-resistance region comprises:
forming a first mask pattern on the doped layer with an opening therein exposing a first area where the capping layer is to be formed;
forming a pre-capping layer by performing a first annealing process in the opening in the first mask pattern;
forming a second mask pattern on the pre-capping layer and the doped layer with an opening therein exposing a second area where the capping layer is to be formed and where the low-resistance region is to be formed; and
forming the capping layer and the low-resistance region by performing a second annealing process in the opening in the second mask pattern.

17. The method of claim 16, wherein the first and second annealing processes are performed at a temperature in a range of about 300° C. to 1000° C. in a vacuum atmosphere.

18. The method of claim 15, wherein forming the capping layer and the low-resistance region comprises:
forming a third mask pattern on the doped layer with an opening therein exposing a third area where the low-resistance region is to be formed; and
forming the low-resistance region by performing an ion implantation process in the opening in the third mask pattern.

19. The method of claim 18, further comprising:
dividing the low-resistance region into a first region and a second region that has a lower resistance than the first region,
wherein dividing the low-resistance region into the first and second regions comprises:
forming a fourth mask pattern on the doped layer with an opening therein exposing a fourth area where the second region is to be formed; and
forming the second region by performing an ion implantation process in the opening in the third mask pattern.

20. The method of claim 18, wherein the ion implantation process comprises ion implantation of one or more of Ar, N, O, Si, and H.
